(19) United States
(12) Patent Application Publication
(10) Pub. No.: US 2014/0116755 A1
(43) Pub. Date: May 1, 2014

(54) LAMINATE CIRCUIT BOARD STRUCTURE

(71) Applicant: KINSUS INTERCONNECT TECHNOLOGY CORP., Taoyuan (TW)

(72) Inventors: Ting-Hao Lin, Taipei (TW); Yu-Te Lu, Taoyuan Hsien (TW); De-Hao Lu, Taoyuan County (TW)

(73) Assignee: KINSUS INTERCONNECT TECHNOLOGY CORP., Taoyuan (TW)

(21) Appl. No.: 13/663,250

(22) Filed: Oct. 29, 2012

(51) Int. Cl. H05K 1/02

(52) U.S. Cl. 174/251

(57) ABSTRACT

A laminate circuit board structure which includes a first circuit metal layer, a first insulation layer, at least one second circuit metal layer, at least one second insulation layer and a support frame is disclosed. The total thickness of the laminate circuit board structure is less than 150 μm. The support frame provided at the outer edge of the co-plane surface formed by the first circuit metal layer and the first insulation layer does not cover the first circuit metal layer, and is formed of at least one metal material. The support frame provides physical support for the entire board structure without influence on the circuit connection so as to prevent the laminate circuit board structure from warping.

### BACKGROUND OF THE INVENTION

1. Field of the Invention

The present invention generally relates to a laminate circuit board structure, and more specifically to a support frame formed of at least one metal material on the surface of the outer edge of the laminate circuit board to enhance the mechanical strength and stability of the entire board.

2. The Prior Arts

Please refer to FIG. 1. The laminate circuit board 500 in the prior arts generally comprises a first circuit metal layer 21, a first insulation layer 31, at least one second circuit metal layer 25, at least one second insulation layer 33 and a solder resist 50.

The first insulation layer 31 is on the first circuit metal layer 21 to cover the upper surface of the first circuit metal layer 21. The lower surface of the first circuit metal layer 21 and the first insulation layer 31 forms a co-plane, on which part of the first circuit metal layer 21 is exposed. The lowermost one of the at least one second circuit metal layer 25 is on the first insulation layer 31 and fills up the openings 35 of the first insulation layer 31 to connect with the first circuit metal layer 21. The lowermost one of the at least one second insulation layer 33 covering the lowermost second circuit metal layer 25 has at least one opening 37 filled by another second circuit metal layer connected with the lowermost second circuit metal layer 25 on the lowermost second insulation layer 33. The uppermost one of the at least one second circuit metal layer 25 is not covered by any one of the at least one second insulation layer 33.

The solder resist 50 is on the co-plane, the uppermost second circuit metal layer 25 and the uppermost second insulation layer 33 to cover part of the first circuit metal layer 21 and part of the uppermost second circuit metal layer 25.

However, one of the shortcomings of the laminate circuit board in the prior arts is that it is difficult to manufacture the board which meets the upcoming requirements for more compact, lighter and smaller electronic products because the board needs to be much thinner with a result that the board easily warps due to insufficient strength during the subsequent processes, such as chip connection, packaging or shipment. Moreover, the circuit layer of the board is easily peeled off or short-circuited and other function failure problems even happen. Therefore, it is desired to provide the laminate circuit board structure which has more mechanical strength and stability and sustains the entire function so as to solve the above-mentioned problems in the prior arts.

### SUMMARY OF THE INVENTION

A primary objective of the present invention is to provide a laminate circuit board structure which has a thickness less than 150 μm and comprises a first circuit metal layer, a first insulation layer, at least one second circuit metal layer, at least one second insulation layer and a support frame.

The first insulation layer is provided on the first circuit metal layer to cover the upper surface of the first circuit metal layer. The lower surface of the first circuit metal layer and the first insulation layer form a co-plane with a surface on which part of the first circuit metal layer is exposed. The lowermost second circuit metal layer is provided on the first insulation layer and fills up at least one opening of the first insulation layer so as to connect with the first circuit metal layer. Generally, the second circuit metal layers and the second insulation layers are arranged in a way that each second circuit metal layer is provided on the corresponding second insulation layer. More specifically, the lowermost second insulation layer is provided on the lowermost second circuit metal, and the uppermost second circuit metal layer is provided on the uppermost second insulation layer. Similarly, two nearest second circuit metal layers are connected via the at least one opening of the corresponding second insulation layer which is filled with the upper one of the two nearest second circuit metal layer. Additionally, the uppermost second circuit metal layer is exposed and not covered by any one second insulation layer.

The support frame formed of at least one metal material is provided on the outer edge of the co-plane surface formed by the first circuit metal layer and the first insulation layer. In particular, the support frame does not cover the first circuit metal layer. Specifically, the support frame may comprise at least a first copper layer, a nickel layer and a second copper layer which are sequentially stacked. Also, a solder resist is further provided on the co-plane surface, the uppermost second circuit metal layer and the uppermost second insulation layer so as to cover part of the first circuit metal layer and the most upper second circuit metal layer.

One aspect of the present invention is that the support frame is provided on the outer edge of the co-plane surface to support the entire board structure without any influence on the circuit connection so as to prevent the laminate circuit board structure from warping.

### BRIEF DESCRIPTION OF THE DRAWINGS

The present invention can be understood in more detail by reading the subsequent detailed description in conjunction with the examples and references made to the accompanying drawings, wherein:

FIG. 1 is a schematic diagram to illustrate the laminate circuit board structure in the prior arts;

FIG. 2A schematically shows a laminate circuit board structure according to the present invention; and

FIG. 2B is a perspective view to schematically illustrate the laminate circuit board structure according to the present invention.

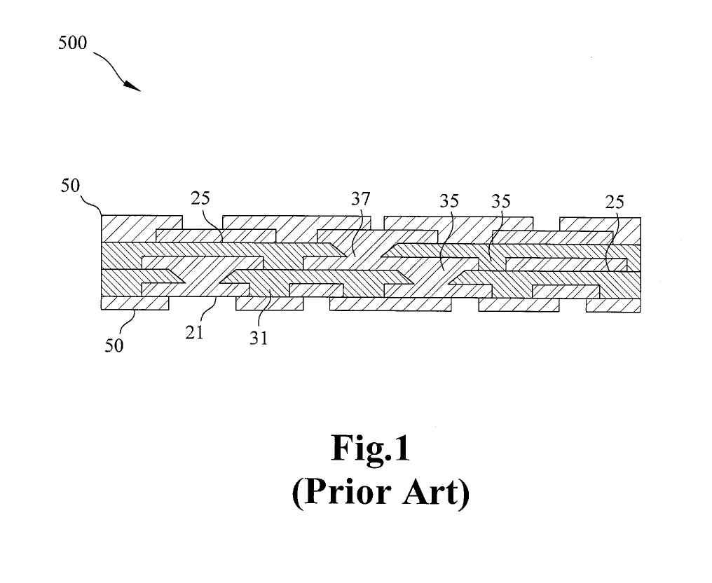

### DETAILED DESCRIPTION OF THE PREFERRED EMBODIMENT

The present invention may be embodied in various forms and the details of the preferred embodiments of the present invention will be described in the subsequent content with reference to the accompanying drawings. The drawings (not to scale) show and depict only the preferred embodiments of the invention and shall not be considered as limitations to the scope of the present invention. Modifications of the shape of the present invention shall too be considered to be within the spirit of the present invention.

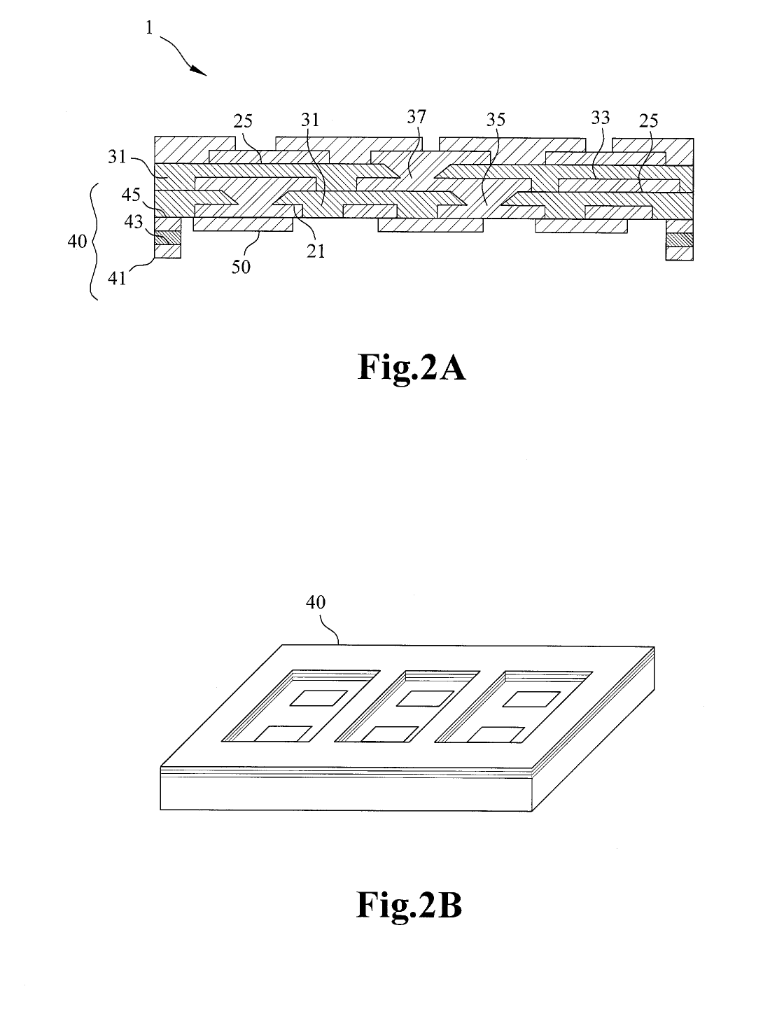

Please refer to FIG. 2A which schematically shows the laminate circuit board structure according to the present invention. As shown in FIG. 2A, the laminate circuit board structure 1 comprises a first circuit metal layer 21, a first insulation layer 31, at least one second circuit metal layer 25, at least one second insulation layer 33, a support frame 40 and a solder resist 50. The thickness of the laminate circuit board structure 1 is less than 150 μm. It should be noted that only two second circuit metal layers 25 and one second insulation layer 33 are shown in FIG. 2A to clearly illustrate the characteristic of the present invention. However, it is not intended to limit the scope of the present invention, and thus the number of the second circuit metal layer 25 and the second insulation layer 33 actually implemented in the laminate circuit board structure of the present invention can be selected as any positive integer.

The first insulation layer 31 is provided on the first circuit metal layer 21 to cover the upper surface of the first circuit metal layer 21. The lower surface of the first circuit metal layer 21 and the first insulation layer 31 form a co-plane surface on which part of the first circuit metal layer 21 is exposed. The lowermost one of the at least second circuit metal layer 25 is provided on the first insulation layer 31 and fills up at least one opening 35 of the first insulation layer 31 so as to connect with the first circuit metal layer 21. Each second circuit metal layer except the uppermost second circuit metal layer is cover by the corresponding second insulation layer. More specifically, the lowermost second insulation layer 33 is provided on the lowermost second circuit metal 25, and the uppermost second circuit metal layer is provided on the uppermost second insulation layer. Similarly, two nearest second circuit metal layers are connected via the at least one opening of the corresponding second insulation layer between the two second circuit metal layers, which is filled with the upper one of the two nearest second circuit metal layers. For example, the at least one opening 37 formed in the lowermost second insulation layer 33 is filled with the lowermost second circuit metal 25 such that the lowermost second circuit metal 25 connects with first circuit metal layer 21. Additionally, the uppermost second circuit metal layer is exposed and not covered by any one second insulation layer.

The support frame 40 formed of at least one metal material is provided on the outer edge of the co-plane surface formed by the first circuit metal layer 21 and the first insulation layer 31. In particular, the support frame 40 does not cover the first circuit metal layer 21. Specifically, the support frame 40 may comprise at least a first copper layer 45, a nickel layer 43 and a second copper layer 41 which are sequentially upwards stacked. The solder resist 50 is provided on the co-plane surface, the uppermost second circuit metal layer and the uppermost second insulation layer so as to cover part of the first circuit metal layer and part of the most upper second circuit metal layer, as shown in FIG. 2A.

Please refer to FIG. 2B illustrating the perspective view of the laminate circuit board structure according to the present invention. The support frame 40 formed on the outer edge of the co-plane surface which is considered as a region of no interest is mainly used to provide enhanced mechanical strength and stability for the entire board structure and meanwhile support the board structure so as to prevent the laminate circuit board structure from warping. Therefore, the present invention successfully solves the troublesome problems, such as board warping, circuit peeling off, short-circuited or even electrical function failure.

One key feature of the laminate circuit board structure according to the present invention is to provide the support frame on the outer edge of the co-plane surface to support the entire structure without any influence on the circuit connection so as to prevent the laminate circuit board structure from warping.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A laminate circuit board structure, comprising:
a first circuit metal layer with a circuit pattern, having an upper surface and a lower surface;
a first insulation layer provided on the first circuit metal layer to cover the upper surface of the first circuit metal layer, and having at least one first opening which exposes part of the first circuit metal layer, wherein the lower surface of the first circuit metal layer and the first insulation layer form a co-plane surface;
at least one second circuit metal layer, wherein each second circuit metal layer forms a circuit pattern, and a lowermost second circuit metal layer of the at least one second circuit metal layer is provided on the first insulation layer and fills up the at least one first opening of the first insulation layer to connect with the part of the first circuit metal layer;
at least one second insulation layer, wherein a lowermost second insulation layer of the at least one second insulation layer is provided on the lowermost second circuit metal layer, and has at least one second opening which exposes part of the lowermost second circuit metal layer, and an another second circuit metal layer of the at least one second circuit metal layer is provided on the lowermost second insulation layer and fills up the at least one second opening of the lowermost second insulation layer to connect with the part of the lowermost second circuit metal layer, and wherein a uppermost second circuit metal layer of the at least one second circuit metal layer is provided on a uppermost second insulation layer of the at least one second insulation layer; and
a support frame formed of at least one metal material and provided on an outer edge of the co-plane surface without covering the first circuit metal layer, wherein the laminate circuit board structure has a thickness less than 150 μm.

2. The laminate circuit board structure as claimed in claim 1, wherein the support frame comprises at least a first copper layer, a nickel layer and a second copper layer sequentially bottom-up stacked and the first copper layer is provided on the co-plane surface.

3. The laminate circuit board structure as claimed in claim 1, further comprising a solder resist, which covers part of the first circuit metal layer and part of the first insulation layer forming the co-plane surface and part of the uppermost second circuit metal layer and part of the uppermost second insulation layer.
